(19) United States
(12) Patent Application Publication
(10) Pub. No.: US 2014/0231849 A1
(43) Pub. Date: Aug. 21, 2014

(54) SEMICONDUCTOR LIGHT-EMITTING DEVICES

(71) Applicant: Samsung Electronics Co., Ltd., Suwon-Si (KR)

(72) Inventors: Sang-Yeob SONG, Suwon-si (KR); Gi-Bum KIM, Hwaseong-si (KR); Hyun-Young KIM, Yongin-si (KR); Ju-Heon YOON, Hwaseong-si (KR); Wan-Ho LEE, Hwaseong-si (KR); Won-Goo HUR, Incheon (KR)

(73) Assignee: SAMSUNG ELECTRONICS CO., LTD., Suwon-Si (KR)

(21) Appl. No.: 14/094,942

(22) Filed: Dec. 3, 2013

(30) Foreign Application Priority Data
Feb. 15, 2013 (KR) 10-2013-0016601

(51) Int. Cl. H01L 33/60

(52) U.S. Cl. CPC H01L 33/60
USPC 257/98

(57) ABSTRACT

Semiconductor light-emitting devices including a semiconductor region that includes a light-emitting structure; and an electrode layer including a first reflection metal layer that contacts a first portion of the semiconductor region and being configured to reflect light from the light-emitting structure and a second reflection metal layer that contacts a second portion of the semiconductor region and being configured to reflect light from the light-emitting structure, wherein the second reflection metal layer is spaced apart from the first reflection metal layer and at least partially covers the first reflection metal layer.

### CROSS-REFERENCE TO RELATED APPLICATIONS

This application claims the benefit of priority under 35 U.S.C. §119 from Korean Patent Application No. 10-2013-0016601, filed on Feb. 15, 2013, in the Korean Intellectual Property Office, the disclosure of which is incorporated herein in its entirety by reference.

### BACKGROUND

1. Field

Example embodiments of the inventive concepts relate to light-emitting devices, and more particularly, to semiconductor light-emitting devices including an electrode formed on a semiconductor layer.

2. Description of Related Art

Light-emitting diodes (LEDs), which are semiconductor light-emitting devices, are widely used in various light-sources, lighting devices, signal lamps, and large display devices used for backlighting. As the LED market for illumination has expanded and products having high current and high output have been required, there is a demand for a technology for improving the reliability of an electrode for electrically connecting a semiconductor layer of an LED to an external structure such as a module and improving light extraction efficiency of a device.

### SUMMARY

An example embodiment of the inventive concepts provides a semiconductor light-emitting device which can improve the reliability of an electrode for electrically connecting a semiconductor layer of a light-emitting diode (LED) to an external structure and improve light extraction efficiency of the semiconductor light-emitting device.

According to an example embodiment of the inventive concepts, there is provided a semiconductor light-emitting device including a semiconductor region including a light-emitting structure; and an electrode layer including a first reflection metal layer contacting a first portion of the semiconductor region. The first reflection metal layer is configured to reflect light from the light-emitting structure. The electrode layer includes a second reflection metal layer contacting a second portion of the semiconductor region. The second reflection metal layer is configured to reflect light from the light-emitting structure. The second reflection metal layer is spaced apart from the first reflection metal layer and at least partially covers the first reflection metal layer.

Each of the first reflection metal layer and the second reflection metal layer may have a reflectance of at least 80% with respect to light generated by the light-emitting structure.

The first reflection metal layer and the second reflection metal layer may be formed of the same material. Alternatively, the first reflection metal layer and the second reflection metal layer may be formed of different materials.

In the semiconductor region, the second portion may have a shape that surrounds the first portion.

The first portion and the second portion may be paced apart from each other. The first portion and the second portion may contact each other at least partially.

The first reflection metal layer may cover a first area of the semiconductor region, and the second reflection metal layer may cover a second area of the semiconductor region. The second area may be greater than the first area.

Each of the first reflection metal layer and the second reflection metal layer may be formed of at least one selected from silver (Ag), aluminum (Al), nickel (Ni), chromium (Cr), palladium (Pd), copper (Cu), platinum (Pt), tin (Sn), tungsten (W), gold (Au), rhodium (Rh), iridium (Ir), ruthenium (Ru), magnesium (Mg), zinc (Zn), and an alloy thereof.

The electrode layer may further include a conductive electrode fixing layer between the first reflection metal layer and the second reflection metal layer, and the electrode layer is formed of a material different from a material of each of the first reflection metal layer and the second reflection metal layer. The conductive electrode fixing layer may include a close-contact layer on the first reflection metal layer; and an adhesive layer between the close-contact layer and the second reflection metal layer. A mechanical adhesive force between the first reflection metal layer and the first portion of the semiconductor region being greater when the close-contact layer is present as opposed to a mechanical adhesive force between the first reflection metal layer and the first portion of the semiconductor region when the close-contact layer is excluded from the conductive electrode fixing layer.

The electrode layer may further include a conductive diffusion barrier film that covers the second reflection metal layer.

The second reflection metal layer may completely cover the first reflection metal layer.

According to another example embodiment of the inventive concepts, there is provided a semiconductor light-emitting device including a semiconductor region including a light-emitting structure having a first semiconductor layer, an active layer, and a second semiconductor layer; a first electrode layer that contacts the first semiconductor layer; and a second electrode layer that contacts the second semiconductor layer. At least one of the first electrode layer and the second electrode layer includes a plurality of reflection metal layers. The plurality of reflection metal layers are spaced apart from one another and overlap with one another. Each of the plurality of reflection metal layers has a reflective surface contacting the semiconductor region.

The plurality of reflection metal layers may include a first reflection metal layer that has a first reflective surface contacting a first portion of the semiconductor region; and a second reflection metal layer that as a second reflective surface contacting a second portion of the semiconductor region.

The semiconductor light-emitting device may further include at least one conductive layer between the first reflection metal layer and the second reflection metal layer, and the at least one conductive layer has a third reflectance lower than a first reflectance of the first reflection metal layer and a second reflectance of the second reflection metal layer.

According to yet another example embodiment, a semiconductor light-emitting device includes a semiconductor region including a light-emitting structure, and a first electrode structure including a first metal layer and a second metal layer spaced apart from each other. The first metal layer and the second metal layer contact different areas of the semiconductor region. The second metal layer extends over the first metal layer. The first metal layer and the second metal layer are configured to reflect light from the light-emitting structure.

The light-emitting structure may include a first semiconductor layer, a second semiconductor layer, and an active layer between the first and second semiconductor layers. A second electrode structure may contact a first surface of the second semiconductor layer. The second semiconductor layer may have a second surface opposing the first surface, and the second surface may be uneven.

The first metal layer and the second metal layer may contact a first area and a second area of the semiconductor region, respectively. The second metal layer may cover an upper surface of the first metal layer.

The first area and the second area of the semiconductor region may abut each other.

### BRIEF DESCRIPTION OF THE DRAWINGS

Example embodiments of the inventive concepts will be more clearly understood from the following detailed description taken in conjunction with the accompanying drawings in which:

FIG. 1A is a cross-sectional view illustrating a semiconductor light-emitting device according to an example embodiment of the inventive concepts;

FIG. 1B is a plan view illustrating a part of a semiconductor layer of the semiconductor light-emitting device of FIG. 1A;

FIG. 1C is a cross-sectional view illustrating a part of a conductive electrode fixing layer of the semiconductor light-emitting device of FIG. 1A;

FIG. 1D is a cross-sectional view illustrating a part of a conductive diffusion barrier film of the semiconductor light-emitting device of FIG. 1A;

FIG. 2A is a cross-sectional view illustrating major elements of a semiconductor light-emitting device according to another example embodiment of the inventive concepts;

FIG. 2B is a plan view illustrating a part of a second semiconductor layer of the semiconductor light-emitting device of FIG. 2A;

FIGS. 3A through 3G are cross-sectional views for explaining a method of manufacturing the semiconductor light-emitting device of FIG. 1A, according to an example embodiment of the inventive concepts;

FIG. 4A is a planar layout illustrating major elements of a semiconductor light-emitting device according to yet another example embodiment of the inventive concepts;

FIG. 4B is a cross-sectional view taken along line 4B-4B′ of FIG. 4A;

FIG. 4C is a view for explaining a first reflection region of a first high-reflection metal layer and a second reflection region of a second high-reflection metal layer of the semiconductor light-emitting device of FIG. 4A;

FIG. 5 is a cross-sectional view illustrating a semiconductor light-emitting device according to still another example embodiment of the inventive concepts;

FIG. 6A is a cross-sectional view illustrating major elements of a semiconductor light-emitting device according to still yet another example embodiment of the inventive concepts;

FIG. 6B is a planar layout for explaining a first reflection region of a first high-reflection metal layer and a second reflection region of a second high reflection meta layer of the semiconductor light-emitting device of FIG. 6A;

FIG. 7 is a cross-sectional view illustrating major elements of a semiconductor light-emitting device according to a further example embodiment of the inventive concepts;

FIG. 8 is a cross-sectional view illustrating major elements of a semiconductor light-emitting device according to a yet further example embodiment of the inventive concepts;

FIG. 9 is a cross-sectional view illustrating major elements of a semiconductor light-emitting device according to a yet still further example embodiment of the inventive concepts;

FIG. 10A is a plan view illustrating major elements of a semiconductor light-emitting device according to an additional example embodiment of the inventive concepts;

FIG. 10B is a cross-sectional view taken along line 10B-10B′ of FIG. 10A;

FIG. 11 is a graph illustrating a result obtained by comparing a light output of a semiconductor light-emitting device according to an example embodiment of the inventive concepts with a light output of a semiconductor light-emitting device according to a comparative example;

FIG. 12 is a cross-sectional view illustrating major elements of a light-emitting device package according to an example embodiment of the inventive concepts;

FIG. 13 is a view illustrating a dimming system including a semiconductor light-emitting device, according to an example embodiment of the inventive concepts; and

FIG. 14 is a block diagram illustrating a display device including a semiconductor light-emitting device, according to an example embodiment of the inventive concepts.

### DETAILED DESCRIPTION OF THE EXAMPLE EMBODIMENTS

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various features will be described in detail with reference to the attached drawings. However, example embodiments described are not limited thereto

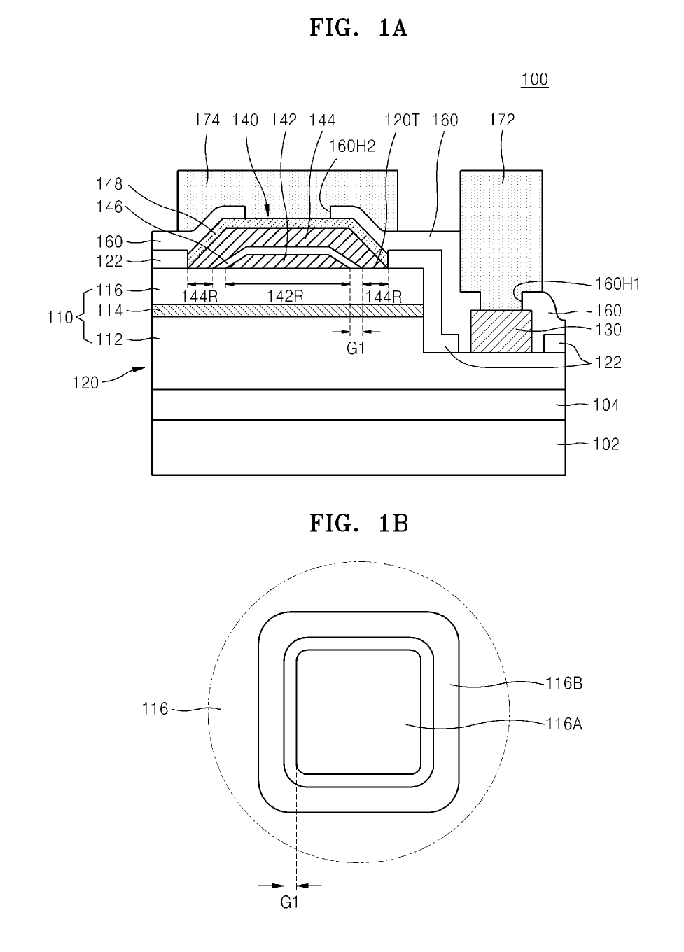

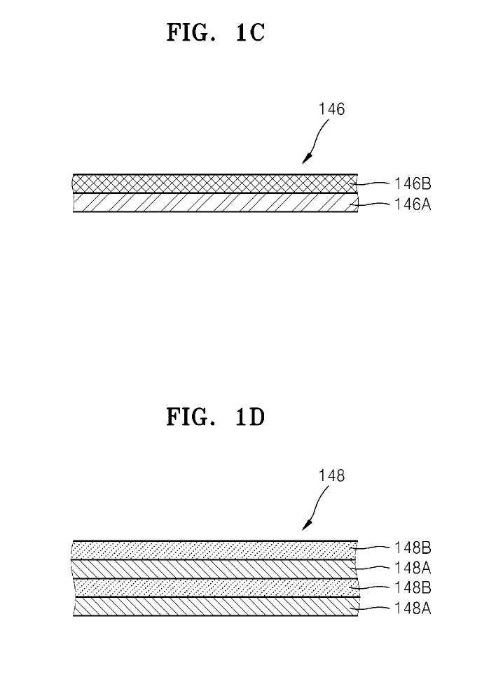

FIG. 1A is a cross-sectional view illustrating a semiconductor light-emitting device according to an example embodiment of the inventive concepts.

Referring to FIG. 1A, a semiconductor light-emitting device 100 includes a substrate 102, a semiconductor region 120 including a light-emitting structure 110 that is formed on the substrate 102, and a first electrode layer 130 and a second electrode layer 140 that are formed on the semiconductor region 120. A part of the semiconductor region 120 is covered by a first insulating film 122. The first insulating film 122 may be formed of an oxide, a nitride, an insulating polymer, or a combination thereof. The first electrode layer 130 and the second electrode layer 140 cover a portion of the semiconductor region 120 not covered by the first insulating film 122.

The substrate 102 may be a transparent substrate. For example, the substrate 102 may be formed of sapphire Al₂O₃, gallium oxide (Ga₂O₃), lithium gallium oxide (LiGaO₂), lithium aluminum oxide (LiAlO₂), or magnesium aluminum oxide (MgAl₂O₄).

The light-emitting structure 110 includes a first semiconductor layer 112, an active layer 114 that is formed on the first semiconductor layer 112, and a second semiconductor layer 116 that is formed on the active layer 114. Each of the first semiconductor layer 112, the active layer 114, and the second semiconductor layer 116 may be formed of a gallium nitride-based compound semiconductor having a composition represented by InₓAl_{y}Ga_{(1-x-y)}N (where 0≦x≦1, 0≦y≦1, and 0≦x+y≦1).

In an example embodiment, the first semiconductor layer 112 may be an n-type GaN layer that supplies electrons to the active layer 114 according to power supply. The n-type GaN layer may include group IV elements as n-type impurities. Examples of the group IV elements may include silicon (Si), germanium (Ge), and tin (Sn).

In an example embodiment, the second semiconductor layer 116 may be a p-type GaN layer that supplies holes to the active layer 120 according to power supply. The p-type GaN layer may include group II elements as p-type impurities. In an example embodiment, examples of the group II elements may include magnesium (Mg), zinc (Zn), and beryllium (Be).

The active layer 114 emits light having predetermined (or, alternatively, set) energy due to recombination between the electrons and the holes. The active layer 114 may have a stacked structure in which a quantum well layer and a quantum barrier layer are alternately stacked at least one time. The quantum well layer may have a single quantum well structure or a multi-quantum well structure. In an example embodiment, the active layer 114 may be formed of u-AlGaN. Alternatively, the active layer 114 may have a multi-quantum well structure formed of GaN/AlGaN, InAlGaN/InAlGaN, or InGaN/AlGaN. In order to improve light-emitting efficiency of the active layer 114, a depth of a quantum well, the number of quantum well layers and quantum barrier layers which are stacked as pairs, and a thickness of the active layer 114 may be changed.

In an example embodiment, the light-emitting structure 110 may be formed by using metal-organic chemical vapor deposition (MOCVD), hydride vapor phase epitaxy (HVPE), or molecular beam epitaxy (MBE).

The semiconductor region 120 further includes a nitride semiconductor thin film 104 that is disposed between the substrate 102 and the light-emitting structure 110. The nitride semiconductor thin film 104 may function as a buffer layer for reducing a lattice mismatch between the substrate 102 and the first semiconductor layer 112. The nitride semiconductor thin film 104 may be formed of a gallium nitride-based compound semiconductor having a composition represented by InₓAl_{y}Ga_{(1-x-y)}N (0≦x≦1, 0≦y≦1, and 0≦x+y≦1). In an example embodiment, the nitride semiconductor thin film 104 may be formed of GaN or AlN. Alternatively, the nitride semiconductor thin film 104 may include AlGaN/AlN superlattice layers. Alternatively, the nitride semiconductor thin film 104 may be omitted.

The first electrode layer 130 is formed on the first semiconductor layer 112. The first electrode layer 130 may have a single-layer structure formed of a material selected from the group consisting of nickel (Ni), aluminum (Al), gold (Au), titanium (Ti), chromium (Cr), silver (Ag), palladium (Pd), copper (Cu), platinum (Pt), tin (Sn), tungsten (W), rhodium (Rh), iridium (Ir), ruthenium (Ru), magnesium (Mg), and zinc (Zn), and an alloy including at least one thereof, or a multi-layer structure formed of a combination thereof. In an example embodiment, the first electrode layer 130 may have a Al/Ti/Pt stacked structure.

The second electrode layer 140 is formed on the second semiconductor layer 116. The second electrode layer 140 directly contacts the second semiconductor layer 116. However, the present example embodiment is not limited thereto. In an example embodiment, another semiconductor layer (not shown) may be further disposed between the second semiconductor layer 116 and the second electrode layer 140.

The second electrode layer 140 includes a first high-reflection metal layer 142 that reflects light from the light-emitting structure 110, and a second high-reflection metal layer 144 that is spaced apart from the first high-reflection metal layer 142 and covers the first high-reflection metal layer 142. The first high-reflection metal layer 142 may contact a portion of the semiconductor region 120, and the second high-reflection metal layer 144 may contact another portion of the semiconductor region 120.

In an example embodiment, each of the first high-reflection metal layer 142 and the second high-reflection metal layer 144 may be formed of a metal or an alloy having a reflectance of at least 80% at a wavelength of light generated by the light-emitting structure 110. For example, a reflectance of Ag is about 98.9%, a reflectance of Al is about 90.3%, a reflectance of Au is about 92.9%, and a reflectance of Cu is about 95.6%. Each of the first high-reflection metal layer 142 and the second high-reflection metal layer 144 may be formed by using each of metals having relatively high reflectances or a combination thereof.

In an example embodiment, each of the first high-reflection metal layer 142 and the second high-reflection metal layer 144 is formed of Ag, Al, Ni, Cr, Pd, Cu, Pt, Sn, W, Au, Rh, Ir, Ru, Mg, Zn, or an alloy including at least one thereof. In an example embodiment, at least one of the first high-reflection metal layer 142 and the second high-reflection metal layer 144 may be formed of Ag, Al, a combination thereof, or an alloy including at least one thereof. When at least one of the first high-reflection metal layer 142 and the second high-reflection metal layer 144 is formed of an Al alloy, the Al alloy may include a metal having a work function higher than that of Al. Alternatively, at least one of the first high-reflection metal layer 142 and the second high-reflection metal layer 144 may be formed of an alloy selected from the group consisting of, but is not limited to, Ag/Pd/Cu, Ag/Pd, Ni/Ag, Zn/Ag, Ni/Al, Zn/Al, Pd/Al, Ir/Ag. Ir/Au, Pt/Ag, Pt/Al, Ni/Ag/Pt, and Ni/Ag/Mg. Alternatively, at least one of the first high-reflection metal layer 142 and the second high-reflection metal layer 144 may include a metal layer that has both ohmic characteristics and light-reflecting characteristics. Alternatively, at least one of the first high-reflection metal layer 142 and the second high-reflection metal layer 144 may have a multi-layer structure in which a first metal film (not shown) having ohmic characteristics and a second metal film (not shown) having light-reflecting characteristics are stacked. For example, at least one of the first high-reflection metal layer 142 and the second high-reflection metal layer 144 may have, but is not limited to, a Ag/Ni/Ti stacked structure or a Ni/Ag/Pt/Ti/Pt stacked structure.

In an example embodiment, the first high-reflection metal layer 142 and the second high-reflection metal layer 144 may be formed of the same material. Alternatively, the first high-reflection metal layer 142 and the second high-reflection metal layer 144 may be formed of different materials.

FIG. 1B is a plan view illustrating a part of the second semiconductor layer 116 of the semiconductor light-emitting device 100 of FIG. 1A.

Referring to FIGS. 1A and 1B, the first high-reflection metal layer 142 includes a first reflection region 142R that contacts a first portion 116A of the second semiconductor layer 116, and the second high-reflection metal layer 144 includes a second reflection region 144R that contacts a second portion 116B of the second semiconductor layer 116.

The second portion 116B may have a shape that surrounds at least a part of the first portion 116A. Although the second portion 116B completely surrounds the first portion 116A in FIG. 1B, the present example embodiment is not limited thereto. For example, the second portion 116B may have a shape that surrounds only a part of the first portion 116A. Also, although the first portion 116A and the second portion 116B have square planar outlines with round corners in FIG. 1B, the present example embodiment is not limited thereto and shapes of the first portion 116A and the second portion 116B may be modified in various ways.

The first portion 116A and the second portion 116B may be spaced apart from each other by a first interval G1. The first interval G1 may have a constant width and a variable size in a longitudinal direction of a space between the first portion 116A and the second portion 116B.

The first high-reflection metal layer 142 and the second high-reflection metal layer 144 are spaced apart from each other, and at least parts of the first high-reflection metal layer 142 and the second high-reflection metal layer 144 overlap with each other in a vertical direction, that is, in a direction perpendicular to a direction in which a main surface of the substrate 102 extends.

In an example embodiment, a first area of the semiconductor region 120 covered by the first high-reflection metal layer 142 may be greater than a second area of the semiconductor region 120 covered by the second high-reflection metal layer 144. An area of the first portion 116A which is a portion where the semiconductor region 120 contacts the first high-reflection metal layer 142 may be less than an area of the second portion 116B which is a portion where the semiconductor region 120 contacts the second high-reflection metal layer 144. However, the present example embodiment is not limited thereto, and various modifications may be made.

Each of the first high-reflection metal layer 142 and the second high-reflection metal layer 144 may have a thickness of, but is not limited to, about 500 to 2500 Å. A thickness of at least a part of the second high-reflection metal layer 144 in the vertical direction perpendicular to the direction in which the main surface of the substrate 102 extends may be greater than a thickness of the first high-reflection metal layer 142 in the vertical direction, but the present example embodiment is not limited thereto.

Because the second electrode layer 140 includes the second high-reflection metal layer 144 that contacts the second semiconductor layer 116 around the first high-reflection metal layer 142 and reflects light from the active layer 114, light extraction efficiency may be further improved by as much as a contact area between the second high-reflection metal layer 144 and the second semiconductor layer 116. That is, because at least part of light emitted around the first high-reflection metal layer 142 from among light generated by the active layer 114 is reflected by the second reflection region 144R of the second high-reflection metal layer 144, the amount of light which does not travel in a desired direction and is substantially lost from among the light generated by the active layer 1147 is minimized, thereby maximizing substantial light extraction efficiency. Also, because a metal which may form an ohmic contact with the second semiconductor layer 116 is used as a material of the second high-reflection metal layer 144, an effective area of the second electrode layer 140 may be higher than that in a case with no second high-reflection metal layer 144 is present. Accordingly, an operating voltage Vf of the semiconductor light-emitting device 100 is reduced, thereby improving efficiency of the semiconductor light-emitting device 100.

The second electrode layer 140 further includes a conductive electrode fixing layer 146 that is disposed between the first high-reflection metal layer 142 and the second high-reflection metal layer 144. The conductive electrode fixing layer 146 may be formed of a material different from that of each of the first high-reflection metal layer 142 and the second high-reflection metal layer 144. In an example embodiment, the conductive electrode fixing layer 146 may have a third reflectance that is lower than a first reflectance of the first high-reflection metal layer 142 and a second reflectance of the second high-reflection metal layer 144. For example, the conductive electrode fixing layer 146 may have a reflectance of about 80% or less. In an example embodiment, the conductive electrode fixing layer 146 may be omitted.

FIG. 1C is a cross-sectional view illustrating a part of the conductive electrode fixing layer 146 of the semiconductor light-emitting device 100 of FIG. 1A.

Referring to FIG. 1C, the conductive electrode fixing layer 146 may have a multi-layer structure including a close-contact layer 146A and an adhesive layer 146B.

The close-contact layer 146A covers at least a part of the first high-reflection metal layer 142. The close-contact layer 146A may be formed right over the first high-reflection metal layer 142. The close-contact layer 146A may be formed to completely cover the first high-reflection metal layer 142, but the present example embodiment is not limited thereto. For example, the close-contact layer 146A may cover only a part of the first high-reflection metal layer 142.

For example, when the first high-reflection metal layer 142 includes Ag, because Ag is thermally and/or chemically unstable, Ag may react with sulfur in the air to generate silver sulfide or may react with oxygen in the air to form an oxide, thereby weakening an adhesive force between the first high-reflection metal layer 142 and the second semiconductor layer 116 or leading to leakage current. However, because the close-contact layer 146A is formed on the first high-reflection metal layer 142, a mechanical adhesive force between the first high-reflection metal layer 142 and the first portion 116A of the second semiconductor layer 116 contacting the first high-reflection metal layer 142 may be increased and thermal and chemical stability of the first high-reflection metal layer 142 may be improved. In an example embodiment, the close-contact layer 146A may be formed of Ni.

The adhesive layer 146B may be disposed between the close-contact layer 146A and the second high-reflection metal layer 144 to improve an adhesive force between the close-contact layer 146A and the second high-reflection metal layer 144. The adhesive layer 146B may be formed on the close-contact layer 146A to cover at least a part of the close-contact layer 146A. In an example embodiment, the adhesive layer 146B may be formed of Ti.

Each of the close-contact layer 146A and the adhesive layer 146B may have a thickness of, but is not limited to, about 30 to 2000 Å.

The second electrode layer 140 further includes a conductive diffusion barrier film 148 that covers at least a part of the second high-reflection metal layer 144.

FIG. 1D is a cross-sectional view illustrating a part of the conductive diffusion barrier film 148 of the semiconductor light-emitting device 100 of FIG. 1A, according to an embodiment of the inventive concepts.

Referring to FIG. 1D, the conductive diffusion barrier film 148 may have a multi-layer structure in which a plurality of conductive layers are alternately stacked at least one time. The plurality of conductive layers include a first conductive layer 148A and a second conductive layer 148B which are alternately stacked. In an embodiment, the first conductive layer 148A may be formed of Ti, and the second conductive layer 148B may be formed of Ni or TiW. Each of the first conductive layer 148A and the second conductive layer 148B may have a thickness of, but is not limited to, about 500 to 1500 Å.

Because the conductive diffusion barrier film 148 prevents a metal material from diffusing from the second electrode layer 140 to the outside, characteristics and reliability of the semiconductor light-emitting device 100 may be prevented from being degraded. Also, because the conductive diffusion barrier film 148 has a multi-layer structure, a stress generated in the second electrode layer 140 may be released. In an example embodiment, the conductive diffusion barrier film 148 may be omitted.

Referring back to FIG. 1A, a second insulating film 160 is formed on the first insulating film 122, the first electrode layer 130, and the second electrode layer 140. A first hole 160H1 through which a part of the first electrode layer 130 is exposed and a second hole 160H2 through which a part of the second electrode layer 140 is exposed are formed in the second insulating film 160.

In an example embodiment, the second insulating film 160 may be formed of an oxide, a nitride, an insulating polymer, or a combination thereof. The second insulating film 160 may be formed of, but is not limited to, the same material as that of the first insulating film 122.

The semiconductor light-emitting device 100 includes a first bonding conductive layer 172 that is connected to the first electrode layer 130, and a second bonding conductive layer 174 that is connected to the second electrode layer 140. Each of the first bonding conductive layer 172 and the second bonding conductive layer 174 may function as an external terminal of the semiconductor light-emitting device 100. The first bonding conductive layer 172 is connected to the first electrode layer 130 through the first hole 160H1 formed in the second insulating film 160. The second bonding conductive layer 174 is connected to the second electrode layer 140 through the second hole 160H2 formed in the second insulating film 160.

Each of the first bonding conductive layer 172 and the second bonding conductive layer 174 may have a single-layer structure formed of a material selected from the group consisting of Au, Sn, Ni, Pb, Ag, In, Cr, Ge, Si, Ti, W, Pt, and an alloy including at least two thereof, or a multi-layer structure formed of a combination thereof. In an example embodiment, each of the first bonding conductive layer 172 and the second bonding conductive layer 174 may include a Au—Sn alloy, a Ni—Sn alloy, a Ni—Au—Sn alloy, a Pb—Ag—In alloy, a Pb—Ag—Sn alloy, a Pb—Sn alloy, a Au—Ge alloy, or a Au—Si alloy.

When each of the first bonding conductive layer 172 and the second bonding conductive layer 174 has a multi-layer structure, each of the first bonding conductive layer 172 and the second bonding conductive layer 174 may include at least two layers selected from the group consisting of a conductive barrier layer (not shown), a conductive adhesive layer (not shown), a conductive coupling layer (not shown), and a conductive bonding layer (not shown). The conductive barrier layer may include at least one selected from the group consisting of Ti, Ti/W, TiN/W, and Ni. The conductive adhesive layer may be formed of Ti. The conductive coupling layer may be formed between the conductive adhesive layer and the conductive bonding layer, and may be formed of Ni or Ni/Au. The conductive bonding layer may include a Au—Sn alloy, a Ni—Sn alloy, a Ni—Au—Sn alloy, a Pb—Ag—In alloy, a Pb—Ag—Sn alloy, a Pb—Sn alloy, a Au—Ge alloy, or a Au—Si alloy. Structures of the first bonding conductive layer 172 and the second bonding conductive layer 174 are not limited thereto, and each of the first bonding conductive layer 172 and the second bonding conductive layer 174 may be formed of a combination of various other conductive materials.

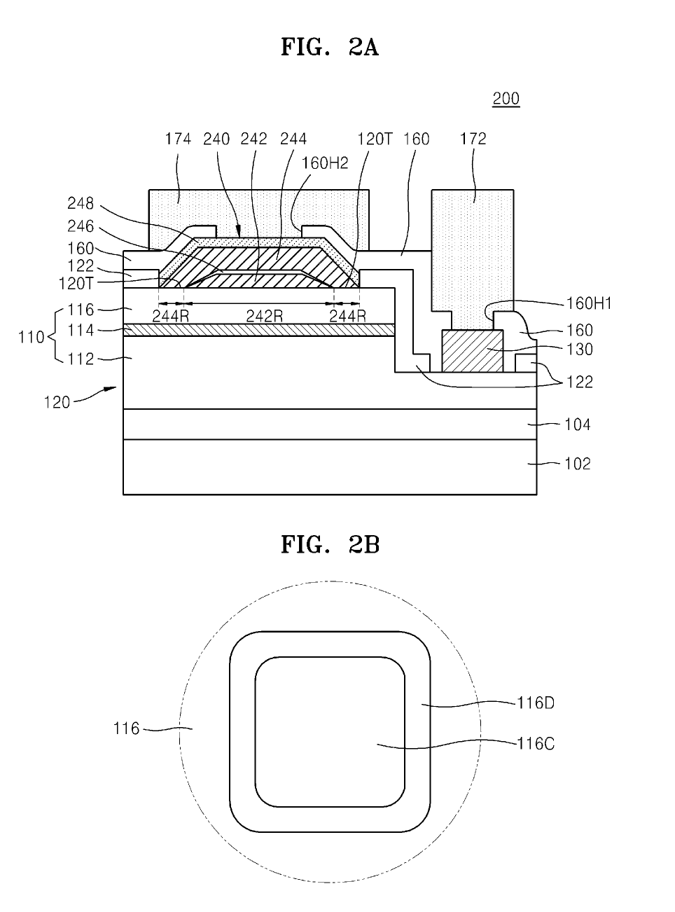

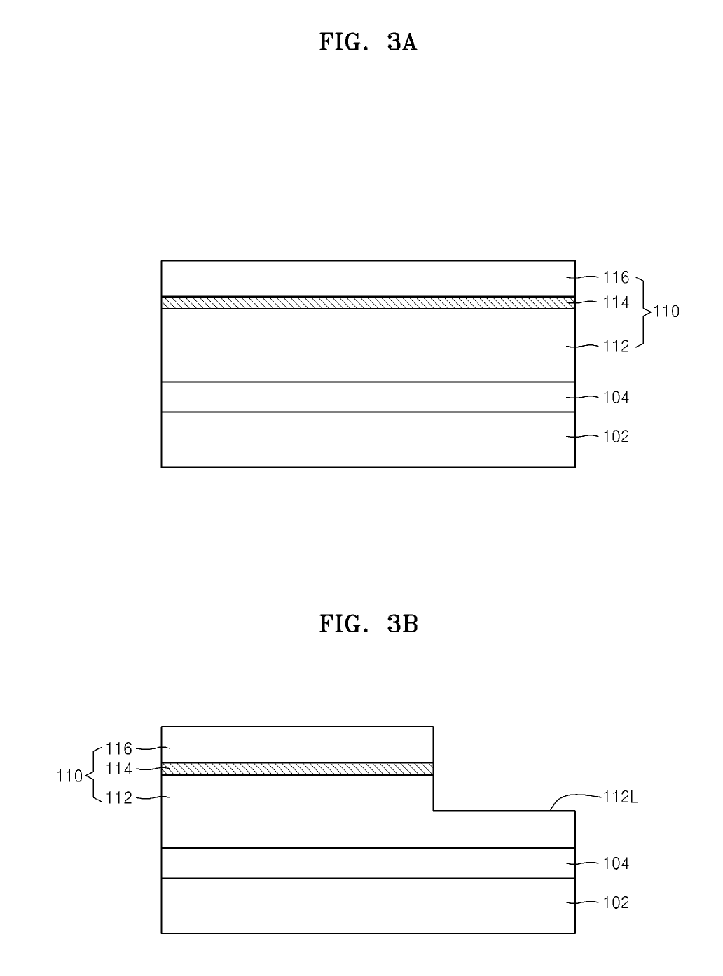

FIG. 2A is a cross-sectional view illustrating major elements of a semiconductor light-emitting device according to another example embodiment of the inventive concepts.

In FIG. 2A, the same elements as those in FIG. 1A are denoted by the same reference numerals, and a repeated explanation thereof will not be given.

Referring to FIG. 2A, a semiconductor light-emitting device 200 is substantially the same as the semiconductor light-emitting device 100 of FIG. 1A except that the semiconductor light-emitting device 200 includes a second electrode layer 240 instead of the second electrode layer 140.

In detail, the second electrode layer 240 is formed on the second semiconductor layer 116. The second electrode layer 240 includes a first high-reflection metal layer 242 that reflects light from the light-emitting structure 110, and a second high-reflection metal layer 244 that is spaced apart from the first high-reflection metal layer 242 and covers the first high-reflection metal layer 242.

FIG. 2B is a plan view illustrating a part of the second semiconductor layer 116 of the semiconductor light-emitting device 200 of FIG. 2A.

In FIGS. 2A and 2B, the first high-reflection metal layer 242 of the second semiconductor layer 116 includes a first reflection region 242R that contacts a first portion 116C of the second semiconductor layer 116, and the second high-reflection metal layer 244 of the second semiconductor layer 116 includes a second reflection region 244R that contacts a second portion 116D of the second semiconductor layer 116.

The second portion 116D may have a shape that surrounds at least a part of the first portion 116C. Although the second portion 116D has a shape that completely surrounds the first portion 116C in FIG. 2B, the present example embodiment is not limited thereto. For example, the second portion 116D may have a shape that surrounds only a part of the first portion 116C.

The first portion 116C and the second portion 116D may contact at least partially. Although the first portion 116C and the second portion 116D completely contact each other along an edge of the first portion 116C in FIG. 2B, the present example embodiment is not limited thereto. For example, the edge of the first portion 116C may have a portion where the first portion 116C and the second portion 116D are spaced apart from each other.

The first high-reflection metal layer 242 and the second high-reflection metal layer 244 are spaced apart from each other at a portion other than an edge portion of the first high-reflection metal layer 242, and at least parts of the first high-reflection metal layer 242 and the second high-reflection metal layer 244 overlap with each other in a vertical direction, that is, in a direction perpendicular to the direction in which the main surface of the substrate 102 extends.

In an example embodiment, a first area of a portion of the semiconductor region 120 covered by the first high-reflection metal layer 242 may be greater than a second area of a portion of the semiconductor region 120 covered by the second high-reflection metal layer 244. An area of the first portion 116C which is a portion where the semiconductor region 120 contacts the first high-reflection metal layer 242 may be less than an area of the second portion which is a portion where the semiconductor region 120 contacts the second high-reflection metal layer 244. However, the present example embodiment is not limited thereto.

The second electrode layer 240 further includes a conductive electrode fixing layer 246 that is disposed between the first high-reflection metal layer 242 and the second high-reflection metal layer 244. In an example embodiment, the conductive electrode fixing layer 246 may not contact the second semiconductor layer 116. To this end, the conductive electrode fixing layer 246 may be formed to have a thickness less than that of the conductive electrode fixing layer 146 of the semiconductor light-emitting device 100 of FIG. 1A. Alternatively, the conductive electrode fixing layer 246 may contact the second semiconductor layer 116 at a portion of an edge of the first high-reflection metal layer 242. Alternatively, the conductive electrode fixing layer 246 may be omitted.

The second electrode layer 240 further includes a conductive diffusion barrier film 248 that covers at least a part of the second high-reflection metal layer 244. In an example embodiment, the conductive diffusion barrier film 248 may be omitted.

The first high-reflection metal layer 242, the second high-reflection metal layer 244, the conductive electrode fixing layer 246, and the conductive diffusion barrier film 248 are substantially the same as the first high-reflection metal layer 142, the second high-reflection metal layer 144, the conductive electrode fixing layer 146, and the conductive diffusion barrier film 148 of the semiconductor light-emitting device 100 of FIGS. 1A through 1D, and thus a detailed explanation thereof will not be given.

Because the second electrode layer 240 includes the second high-reflection metal layer 244 that contacts the second semiconductor layer 116 around the first high-reflection metal layer 242 and emits light from the active layer 114, light extraction efficiency may be further improved by as much as a contact area between the second high-reflection metal layer 244 and the second semiconductor layer 116, thereby maximizing light extraction efficiency. Also, because a metal that may form an ohmic contact with the second semiconductor layer 116 is used as a material of the second high-reflection metal layer 244, an effective area of the second electrode layer 240 may be higher than that in a case with no second high-reflection metal layer 244. Accordingly, the operating voltage Vf of the semiconductor light-emitting device 100 is reduced, thereby improving efficiency of the semiconductor light-emitting device 100.

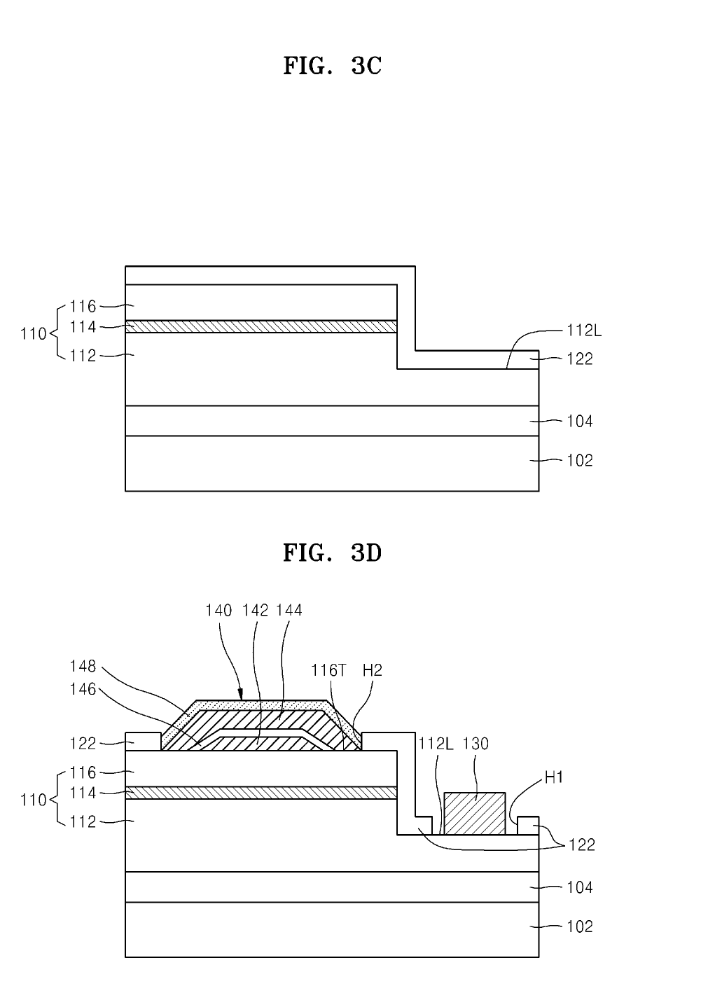

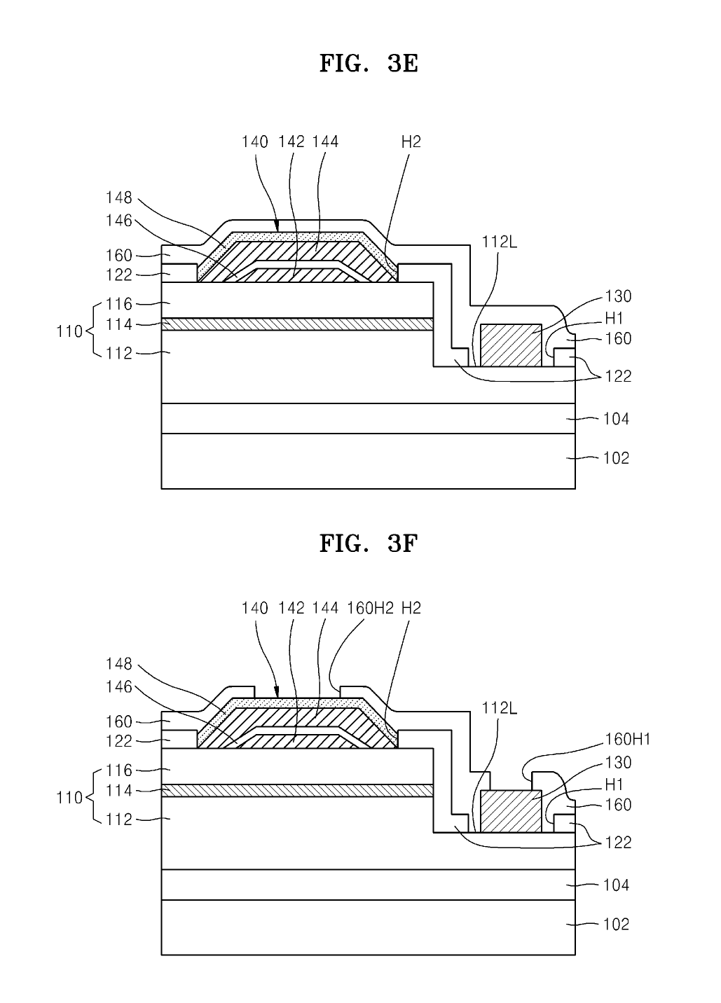

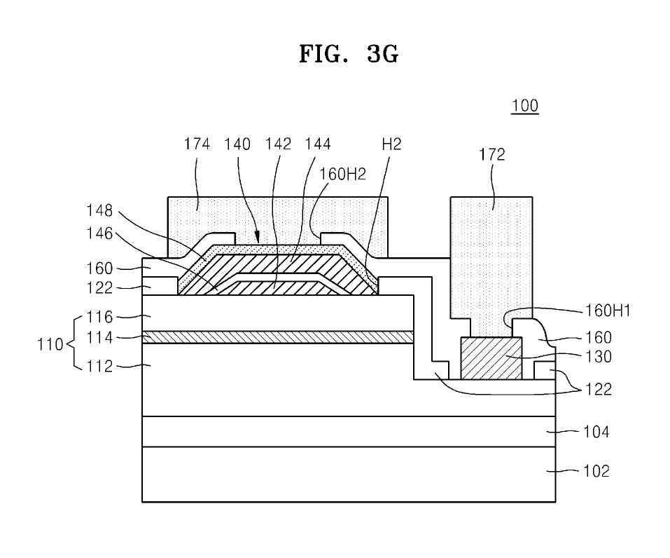

FIGS. 3A through 3G are cross-sectional views for explaining a method of manufacturing the semiconductor light-emitting device of FIG. 1A.

In FIGS. 3A through 3G, the same elements as those in FIG. 1A are denoted by the same reference numerals, and a detailed explanation thereof will not be given for briefness.

Referring to FIG. 3A, the nitride semiconductor thin film 104 and the light-emitting structure 110 including the first semiconductor layer 112, the active layer 114, and the second semiconductor layer 116 are formed on the substrate 102.

In an example embodiment, the light-emitting structure 110 may be formed by using MOCVD, HVPE, or MBE.

Referring to FIG. 3B, a low surface portion 112L of the first semiconductor layer 112 is formed by mesa-etching a part of the light-emitting structure 110 to a predetermined (or, alternatively, set) depth of the first semiconductor layer 112 from the second semiconductor layer 116.

The mesa-etching of the light-emitting structure 140 may be performed by using reactive ion etching (RIE).

Referring to FIG. 3C, the first insulating film 122 that covers an exposed surface of the low surface portion 112L of the first semiconductor layer 112, and the light-emitting structure 110 is formed.

The first insulating film 122 may be formed of, but is not limited to, a silicon oxide film, a silicon nitride film, an insulating polymer, or a combination thereof. In an example embodiment, the first insulating film 122 may be formed by using PECVD, PVD, or spin coating.

Referring to FIG. 3D, a hole H1 through which the lower surface portion 112L of the first semiconductor layer 112 is exposed is formed by etching a part of the first insulating film 122, and the first electrode layer 130 that is connected to the first semiconductor layer 112 through the hole H1 is formed.

Next, a hole H2 through which a top surface 116T of the second semiconductor layer 116 is exposed is formed by etching another part of the first insulating film 122, and then the second electrode layer 140 that is connected to the second semiconductor layer 116 through the hole H2 is formed.

In an example embodiment, the holes H1 and H2 may be formed in the first insulating film 122 by using RIE or wet etching using a buffered oxide etchant (BOE).

In an example embodiment, the first electrode layer 130 may be formed by using directed vapor deposition (DVD) using electron beam evaporation.

In an example embodiment, a process of forming the second electrode layer 140 may include a process of forming the first high-reflection metal layer 142 by using DVD using electron beam evaporation, and a process of sequentially forming the conductive electrode fixing layer 146, the second high-reflection metal layer 144, and the conductive diffusion barrier film 148 by using sputtering.

Although the first electrode layer 130 is formed and then the second electrode layer 140 is formed in the present example embodiment, an order in which the first electrode layer 130 and the second electrode layer 140 are formed is not limited thereto. For example, the second electrode layer 140 may be first formed and then the first electrode layer 130 may be formed.

Referring to FIG. 3E, the second insulating film 160 that covers the first insulating film 122, the first electrode layer 130, and the second electrode layer 140 is formed.

The second insulating film 160 may be formed of, but is not limited to, a silicon oxide film, a silicon nitride film, an insulating polymer, or a combination thereof. In an embodiment, the second insulating film 160 may be formed by using PECVD, PVD, or spin coating.

Referring to FIG. 3F, the first hole 160H1 through which a part of the first electrode layer 130 is exposed and the second hole 160.H2 through which a part of the second electrode layer 140 is exposed are formed by etching a part of the second insulating film 160.

In order to form the first hole 160H1 and the second hole 160H2, a mask pattern (not shown) in which a plurality of holes through which a part of the second insulating film 160 is exposed are formed may be formed on the second insulating film 160, and the second insulating film 160 may be etched by using the mask pattern as an etch mask. Next, the second insulating film 160 may be exposed by removing the mask pattern used as the etch mask. The second insulating film 160 may be etched by using RIE.

Referring to FIG. 3G, the first bonding conductive layer 172 that is connected to the first electrode layer 130 through the first hole 160H1 and the second bonding conductive layer 174 that is connected to the second electrode layer 140 through the second hole 160H2 are formed.

In an example embodiment, the semiconductor light-emitting device 100 manufactured by using the method may be mounted on a package substrate (not shown) by using eutectic bonding by using the first bonding conductive layer 172 and the second bonding conductive layer 174 as bonding layers.

Although the method of manufacturing the semiconductor light-emitting device 100 of FIG. 1A has been described with reference to FIGS. 3A through 3G, it would be understood by one of ordinary skill in the art that the semiconductor light-emitting device 200 of FIG. 2A may be manufactured by using a method similar to the method.

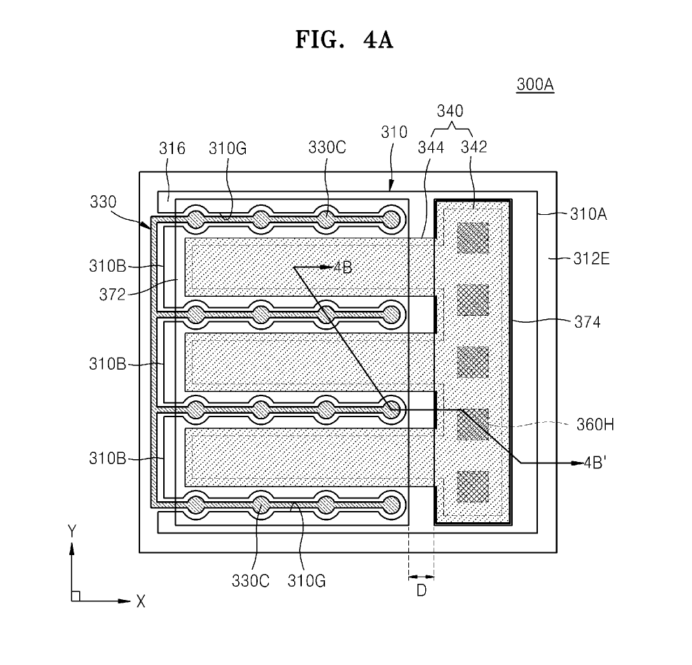

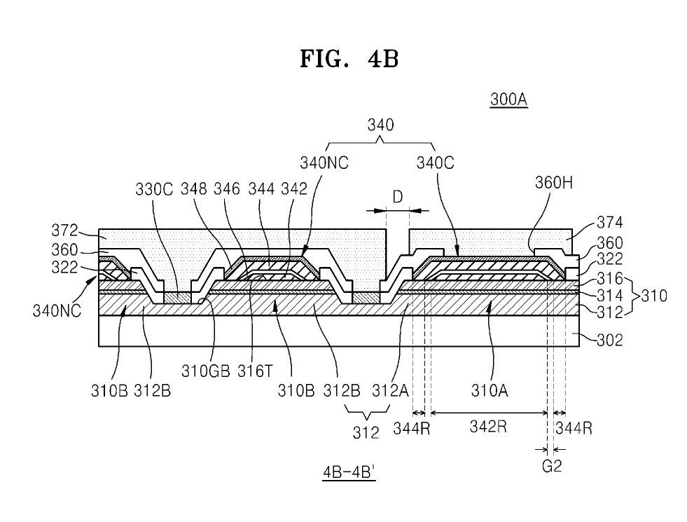

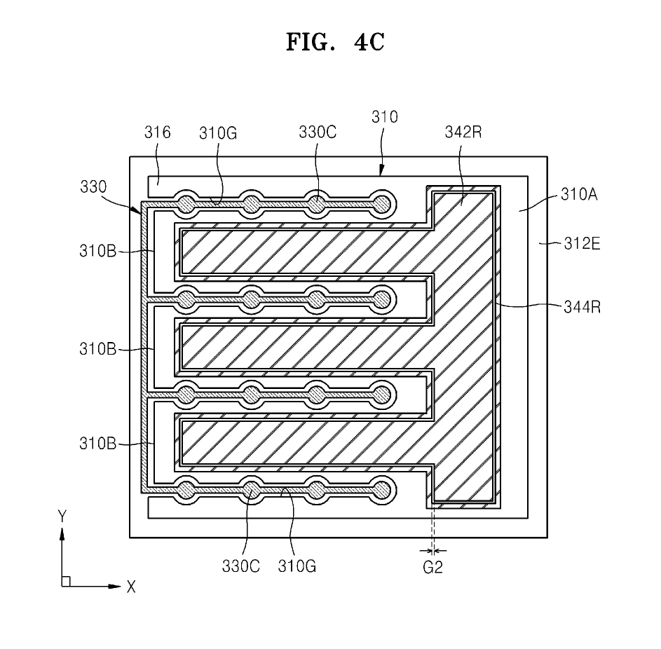

FIG. 4A is a planar layout illustrating major elements of a semiconductor light-emitting device 300A according to another example embodiment of the inventive concepts. FIG. 4B is a cross-sectional view taken along line 4B-4B′ of FIG. 4A. FIG. 4C is a view for explaining a first reflection region of a first high-reflection metal layer and a second reflection region of a second high-reflection metal layer included in a second electrode layer 340 of the semiconductor light-emitting device 300A of FIG. 4A.

Referring to FIGS. 4A through 4C, the semiconductor light-emitting device 300A includes a substrate 302, and a light-emitting structure 310 that is formed on the substrate 302.

The substrate 302 may have the same structure as that of the substrate 102 of FIG. 1A.

Grooves 310GB are formed in a portion of the light-emitting structure 310. The light-emitting structure 310 includes a first mesa structure 310A that extends in a first direction (Y direction in FIG. 4A) on the substrate 302, and a plurality of second mesa structures 310B that are spaced apart from one another with the grooves 310B therebetween and are connected to one another through the first mesa structure 310A at one ends thereof.

The light-emitting structure 310 includes a first semiconductor layer 312, an active layer 314, and a second semiconductor layer 316 that are sequentially formed on the substrate 302.

The first semiconductor layer 312 includes first and second mesa regions 312A and 312B having a plurality of branching portions that are spaced apart from one another due to the grooves 310G. That is, the first semiconductor layer 312 includes the first mesa region 312A that constitutes a part of the first mesa structure 310A, and the plurality of second mesa regions 312B that are spaced apart from one another with the grooves 310G therebetween and are connected to one another through the first mesa region 312A at one ends thereof.

A low surface portion 312E of the first semiconductor layer 312 is exposed around the light-emitting structure 310 on an edge portion of the substrate 302. The low surface portion 312E of the first semiconductor layer 312 is on almost the same level as bottom surfaces 310GB of the grooves 310G, and is connected to the bottom surfaces 310GB of the grooves 310G. The low surface portion 312E of the first semiconductor layer 312 may be used as a scribing line during a subsequent process for separating the substrate 302 in units of chips. In an example embodiment, the first semiconductor layer 312 may not include the low surface portion 312E.

The first semiconductor layer 312 may be formed of an n-type semiconductor, and the second semiconductor layer 316 may be formed of a p-type semiconductor. The first semiconductor layer 312, the active layer 314, and the second semiconductor layer 316 are substantially the same as the first semiconductor layer 112, the active layer 114, and the second semiconductor layer 116 of FIG. 1A, and thus a detailed explanation thereof will not be given.

A portion of the first semiconductor layer 312 is exposed on the bottom surfaces 310GB of the grooves 310G. A first electrode layer 330 is formed on the portion of the first semiconductor layer 312 which is exposed on the bottom surfaces 310GB of the grooves 310G. The first electrode layer 330 extends in a longitudinal direction of the grooves 310G. The first electrode layer 330 has a plurality of contact regions 330C that are disposed in the grooves 310G. Although the plurality of contact regions 330C have greater widths than other portions of the first electrode layer 330, the present example embodiment is not limited thereto. The first electrode layer 330 is substantially the same as the first electrode layer 130 of FIG. 1A, and thus a detailed explanation thereof will not be given.

A second electrode layer 340 is formed on the light-emitting structure 310. The second electrode layer 340 is connected to the second semiconductor layer 316.

The second electrode layer 340 is disposed on the light-emitting structure 310 to overlap with the first mesa structure 310A and the plurality of second mesa structures 310B branching from the first mesa structure 310A. A portion of the second electrode layer 340 disposed on the first mesa structure 310A constitutes a contact region 340C, and another portion of the second electrode layer 340 disposed on the plurality of second mesa structures 310B constitutes a non-contact region 340NC.

The second electrode layer 340 includes a first high-reflection metal layer 342 that reflects light from the light-emitting structure 310, and a second high-reflection metal layer 344 that is spaced apart from the first high-reflection metal layer 342 and covers the first high-reflection metal layer 342.

As shown in FIG. 4C, the first high-reflection metal layer 342 includes a first reflection region 342R that contacts a portion of the second semiconductor layer 316, and the second high-reflection metal layer 344 includes a second reflection region 344R that contacts another portion of the second semiconductor layer 316. The second reflection region 344R may have a shape that surrounds at least a part of the first reflection region 342R with a second interval G2 therebetween. Although the second reflection region 344R has a shape that completely surrounds the first reflection region 342R in FIG. 4C, the present example embodiment is not limited thereto. For example, the second reflection region 344R may have a shape that surrounds only a part of the first reflection region 342R. Although the second reflection region 344R and the first reflection region 342R are spaced apart from each other, like in the semiconductor light-emitting device 100 of FIGS. 1A and 1B, the present example embodiment is not limited thereto. For example, the second reflection region 344R and the first reflection region 342r may contact each other, like in the semiconductor light-emitting device 200 of FIGS. 2A and 2B.

At least parts of the first high-reflection metal layer 342 and the second high-reflection metal layer 344 may overlap with each other in a vertical direction, that is, in a direction perpendicular to a direction in which a main surface of the substrate 302 extends.

The second electrode layer 340 further includes a conductive electrode fixing layer 346 that is disposed between the first high-reflection metal layer 342 and the second high-reflection metal layer 344. As shown in FIG. 4B, the conductive electrode fixing layer 346 may have a portion contacting the second semiconductor layer 316. In an embodiment, the conductive electrode fixing layer 346 may not contact the second semiconductor layer 116, like in the semiconductor light-emitting device 200 of FIGS. 2A and 2B.

The second electrode layer 340 further includes a conductive diffusion barrier film 348 that covers at least a part of the second high-reflection metal layer 344. In an embodiment, the conductive diffusion barrier film 348 may be omitted.

The first high-reflection metal layer 342, the second high-reflection metal layer 344, the conductive electrode fixing layer 346, and the conductive diffusion barrier film 348 are substantially the same as the first high-reflection metal layer 142, the second high-reflection metal layer 144, the conductive electrode fixing layer 146, and the conductive diffusion barrier film 148 of FIGS. 1A through 1D, and thus a detailed explanation thereof will not be given.

Because the second electrode layer 340 includes the second high-reflection metal layer 344 that contacts the second semiconductor layer 316 around the first high-reflection metal layer 342 and emits light from the active layer 314, light extraction efficiency may be further improved by as much as a contact area between the second high-reflection metal layer 344 and the second semiconductor layer 116, thereby maximizing light extraction efficiency. Also, because a metal that may form an ohmic contact with the second semiconductor layer 316 is used as a material of the second high-reflection metal layer 344, an effective area of the second electrode layer 340 may be higher than that in a case with no second high-reflection metal layer 344. Accordingly, an operating voltage Vf of the semiconductor light-emitting device 300A is reduced, thereby improving efficiency of the semiconductor light-emitting device 300A.

A first insulating film 322 is formed between the first electrode layer 330 and the second electrode layer 340. The first insulating film 322 covers side walls of the first mesa structure 310A and the plurality of second mesa structures 310B branching from the first mesa structure 310A of the light-emitting structure 310.

The non-contact region 340NC of the second electrode layer 340 is covered by a second insulating film 360. The second insulating film 360 covers a side wall of the light-emitting structure 310 with the first insulating film 322 therebetween.

A first bonding conductive layer 372 that is connected to a plurality of contact regions 330C of the first electrode layer 330, and a second bonding conductive layer 374 that is connected to a contact region 340C of the second electrode layer 340 are formed on the second insulating film 360. The first bonding conductive layer 372 and the second bonding conductive layer 374 are spaced apart from each other by a predetermined (or, alternatively, set) interval D.

The first bonding conductive layer 372 contacts the second insulating film 360 and the plurality of contact regions 340C of the first electrode layer 330 on the plurality of second mesa structures 310B, and extends to overlap with the plurality of second mesa structures 310B. The first bonding conductive layer 372 covers the non-contact region 340NC of the second electrode layer 340 with the second insulating film 360 therebetween. The first bonding conductive layer 372 and the non-contact region 340NC of the second electrode layer 340 may be insulated from each other due to the second insulating film 360 that is disposed between the first bonding conductive layer 372 and the non-contact region 340NC of the second electrode layer 340.

The second bonding conductive layer 374 is connected to the contact region 340C of the second electrode layer 340 through a plurality of holes 360H formed in the second insulating film 360.

The first bonding conductive layer 372 and the second bonding conductive layer 374 are substantially the same as the first bonding conductive layer 172 and the second bonding conductive layer 174 of FIG. 1A, and thus a detailed explanation thereof will not be given.

The semiconductor light-emitting device 300A of FIGS. 4A through 4C may be easily manufactured by using the method of manufacturing the semiconductor light-emitting device 100 described with reference to FIGS. 3A through 3G. Accordingly, a detailed explanation of a method of manufacturing the semiconductor light-emitting device 300A will not be given.

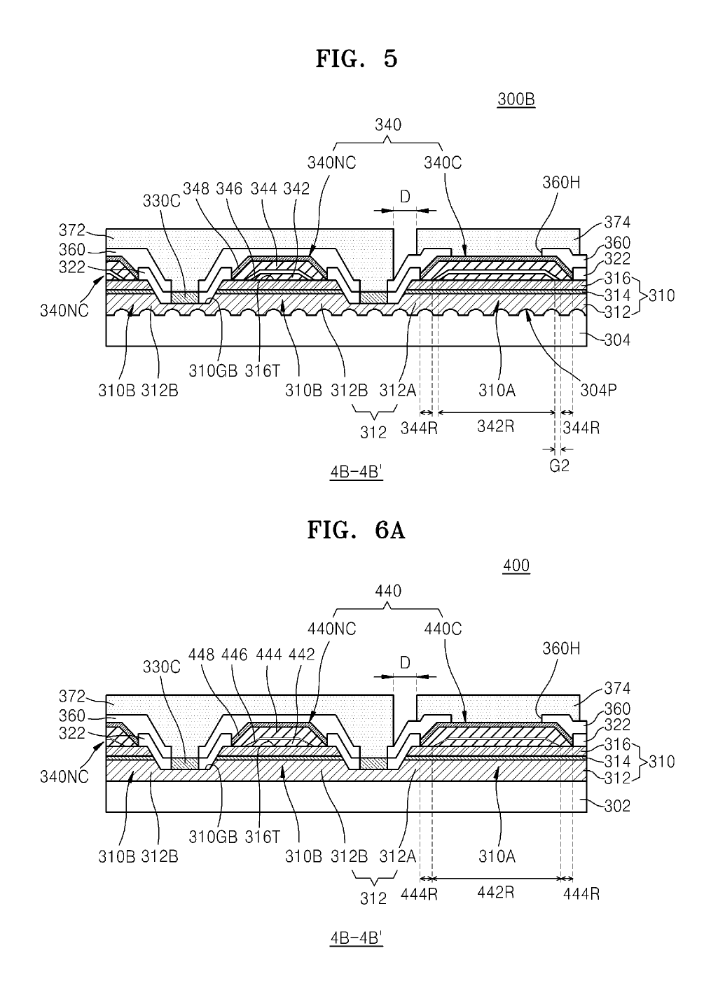

FIG. 5 is a cross-sectional view illustrating a semiconductor light-emitting device according to still another example embodiment of the inventive concepts.

In FIG. 5, the same elements as those in FIGS. 4A through 4Ca re denoted by the same reference numerals, and a detailed explanation thereof will not be given for briefness.

Referring to FIG. 5, a semiconductor light-emitting device 300B has substantially the same structure as that of the semiconductor light-emitting device 300A of FIGS. 4A through 4C except that an uneven pattern 340P is formed on a surface of a substrate 304 facing the first semiconductor layer 312. The substrate 304 is substantially the same as the substrate 302 of FIGS. 4A through 4C, and thus a detailed explanation thereof will not be given.

Because the uneven pattern 304P is formed on the surface of the substrate 304, crystallinity of semiconductor layers formed on the substrate 304 is improved and a defect density is reduced, thereby improving internal quantum efficiency. Extraction efficiency due to diffused reflection of light on the surface of the substrate 304 is improved, thereby improving light extraction efficiency of the semiconductor light-emitting device 300B.

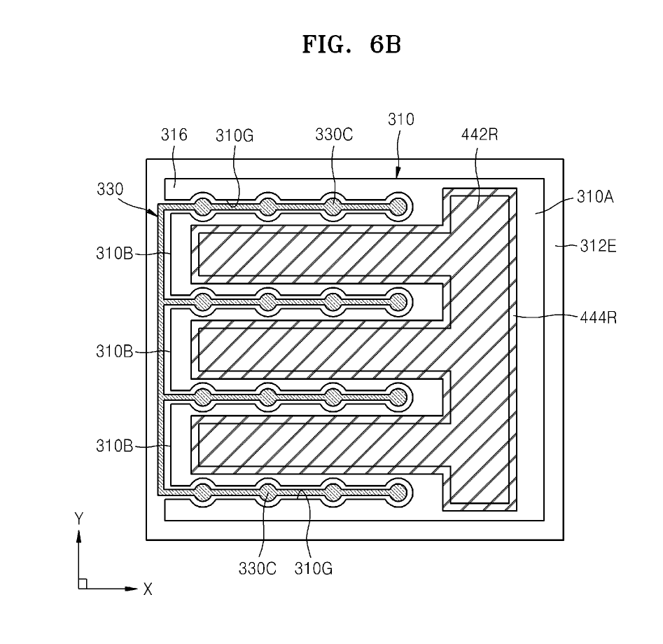

FIG. 6A is a cross-sectional view illustrating major elements of a semiconductor light-emitting device according to still yet another example embodiment of the inventive concepts. FIG. 6B is a planar layout for explaining a first reflection region of a first high-reflection metal layer and a second reflection region of a second high-reflection metal layer included in a second electrode layer of the semiconductor light-emitting device of FIG. 6A.

Referring to FIGS. 6A and 6B, a semiconductor light-emitting device 400 has substantially the same structure as that of the semiconductor light-emitting device 300A of FIG. 4A except that the semiconductor light-emitting device 400 includes the second electrode layer 440 instead of the second electrode layer 340.

In detail, the second electrode layer 440 is formed on the second semiconductor layer 316. The second electrode layer 440 includes the first high-reflection metal layer 442 that reflects light from the light-emitting structure 3140, and the second high-reflection metal layer 444 that is spaced apart from the first high-reflection metal layer 442 and covers the first high-reflection metal layer 442.

The first high-reflection metal layer 442 includes the first reflection region 442R that contacts a portion of the second semiconductor layer 316, and the second high-reflection metal layer 444 includes the second reflection region 444R that contacts another portion of the second semiconductor layer 316.

The second reflection region 444R may have a shape that surrounds at least a part of the first reflection region 442R. Although the second reflection region 444R has a shape that completely surrounds the first reflection region 442R in FIG. 6B, the present embodiment is not limited thereto. For example, the second reflection region 444R may have a shape that surrounds only a part of the first reflection region 442R.

The first reflection region 442R and the second reflection region 444R may contact each other at least partially. Although the first reflection region 442R and the second reflection region 444R completely contact each other along an edge of the first reflection region 442R in FIG. 6B, the present embodiment is not limited thereto. For example, the edge of the first reflection region 442R may have a portion where the first reflection region 442R and the second reflection region 444R are spaced apart from each other.

The first high-reflection metal layer 442 and the second high-reflection metal layer 444 are spaced apart from each other at a portion other than an edge portion of the first high-reflection metal layer 442, and at least parts of the first high-reflection metal layer 442 and the second high-reflection metal layer 444 overlap with each other in a vertical direction, that is, in a direction perpendicular to the direction in which the main surface of the substrate 302 extends.

In an example embodiment, a first area of a portion of the second semiconductor layer 316 covered by the first high-reflection metal layer 442 may be greater than a second area of a portion of the second semiconductor layer 316 covered by the second high-reflection metal layer 444. An area of the first reflection region 442R of the first high-reflection metal layer 442 contacting the second semiconductor layer 316 may be less than an area of the second reflection region 444R of the second high-reflection metal layer 244 contacting the second semiconductor layer 316. However, the present example embodiment is not limited thereto.

The second electrode layer 440 further includes a conductive electrode fixing layer 446 that is disposed between the first high-reflection metal layer 442 and the second high-reflection metal layer 444. In an example embodiment, the conductive electrode fixing layer 446 may not contact the second semiconductor layer 116. To this end, the conductive electrode fixing layer 446 may be formed to have a thickness less than that of the conductive electrode fixing layer 316 of the semiconductor light-emitting device of FIG. 4B. Alternatively, the conductive electrode fixing layer 446 may contact the second semiconductor layer 316 at a portion of an edge of the first high-reflection metal layer 442.

The second electrode layer 440 further includes a conductive diffusion barrier film 448 that covers at least a part of the second high-reflection metal layer 444. In an example embodiment, the conductive diffusion barrier film 448 may be omitted.

The first high-reflection metal layer 442, the second high-reflection metal layer 444, the conductive electrode fixing layer 446, and the conductive diffusion barrier film 448 are substantially the same as the first high-reflection metal layer 142, the second high-reflection metal layer 144, the conductive electrode fixing layer 146, and the conductive diffusion barrier film 148 of FIGS. 1A through 1D, and thus a detailed explanation thereof will not be given.

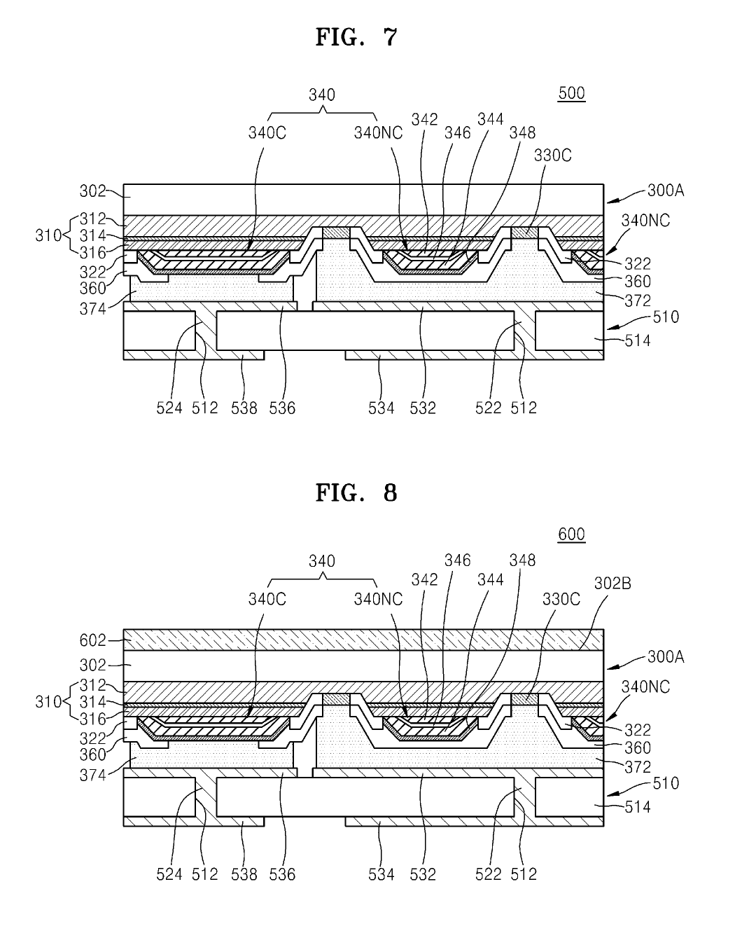

FIG. 7 is a cross-sectional view illustrating major elements of a semiconductor light-emitting device according to a further example embodiment of the inventive concepts.

A semiconductor light-emitting device 500 has a structure in which the semiconductor light-emitting device 300A of FIGS. 4A through 4C is mounted on a package substrate 510.

In FIG. 7, the same elements as those in FIGS. 4A through 4C are denoted by the same reference numerals, and a detailed explanation thereof will not be given.

Referring to FIG. 7, a package substrate 510 includes a substrate body 514 in which a plurality of through-holes 512 are formed, a plurality of through-electrodes 522 and 524 that are formed in the plurality of through-holes 512, and a plurality of conductive layers formed on both surfaces of the substrate body 514. The plurality of conductive layers include a first conductive layer 532 and a second conductive layer 534 that are formed on the both surfaces of the substrate 514 and are respectively connected to both ends of the through-electrode 522, and a third conductive layer 536 and a fourth conductive layer 538 that are formed on the both surfaces of the substrate body 514 and are respectively connected to both ends of the through-electrode 524. The first conductive layer 532 and the third conductive layer 536 formed on one surface of the substrate body 514 are spaced apart from each other, and the second conductive layer 534 and the fourth conductive layer 538 formed on the other surface of the substrate body 514 are spaced apart from each other.

The substrate body 514 may be a circuit substrate such as a printed circuit board (PCB), a metal core PCB (MCPCB), a metal PCB (MPCB), or a flexible PCB (FPCB), or a ceramic substrate formed of MN or Al₂O₃. In an example embodiment, a structure including a lead frame instead of the package substrate 510 of FIG. 7 may be used.

Each of the through-electrodes 522 and 524 and the first through fourth conductive layers 532, 534, 536, and 538 may be formed of Cu, Au, Ag, Ni, W, C, or a combination thereof.

The first bonding conductive layer 372 is connected to the first conductive layer 532, and the second bonding conductive layer 374 is connected to the third conductive layer 536. The first bonding conductive layer 372 and the second bonding conductive layer 374 may be bonded to the first conductive layer 532 and the second conductive layer 536, respectively, by using eutectic die bonding. To this end, the semiconductor light-emitting device 300A of FIGS. 4A and 4B may be disposed on the package substrate 510 such that the first bonding conductive layer 372 and the second bonding conductive layer 374 respectively face the first conductive layer 532 and the third conductive layer 536, and then thermo-compression may be performed at a temperature of about 200 to 700° C. Because the first bonding conductive layer 372 and the first conductive layer 532, and the second bonding conductive layer 374 and the third conductive layer 536 are bonded to each other by using eutectic die bonding, an adhesive force having high reliability and high strength may be maintained.

Although the semiconductor light-emitting device 300A of FIGS. 4A and 4B is mounted on the package substrate 510 in FIG. 7, the semiconductor light-emitting device 300B of FIG. 5 or the semiconductor light-emitting device 400 of FIG. 6a may be mounted on the package substrate 510 by using a method similar to the method described with reference to FIG. 7.

FIG. 8 is a cross-sectional view illustrating major elements of a semiconductor light-emitting device according to a yet further example embodiment of the inventive concepts.

In FIG. 8, the same elements as those in FIGS. 4A through 7 are denoted by the same reference numerals, and a detailed explanation thereof will not be given.

Referring to FIG. 8, a semiconductor light-emitting device 600 has substantially the same structure as that of the semiconductor light-emitting device 500 of FIG. 7 except that a rear surface 302B of the substrate 302 is covered by a wavelength conversion unit 602.

The wavelength conversion unit 602 may function to convert a wavelength of light emitted from the light-emitting structure 310 of the semiconductor light-emitting device 300A into another wavelength. In an example embodiment, the wavelength conversion unit 602 may include a resin layer including phosphors or quantum dots.

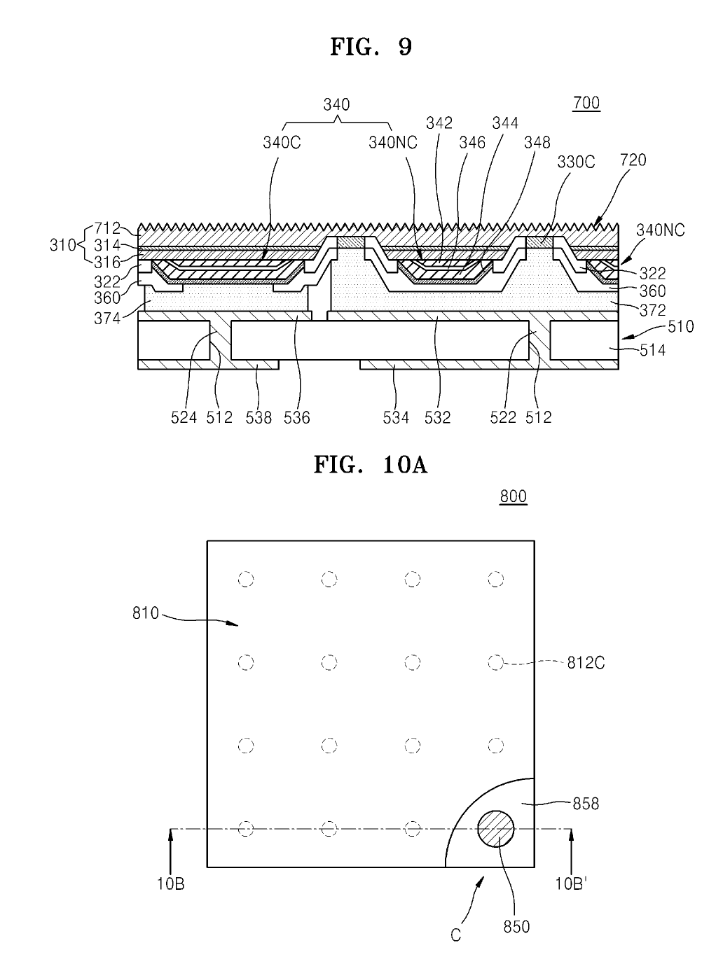

FIG. 9 is a cross-sectional view illustrating major elements of a semiconductor light-emitting device according to a yet still further example embodiment of the inventive concepts.

In FIG. 9, the same elements as those in FIGS. 4A through 8 are denoted by the same reference numerals, and a detailed explanation thereof will not be given.

Referring to FIG. 9, a semiconductor light-emitting device 700 includes a first semiconductor layer 712 having an uneven surface 720. In an exemplary process for manufacturing the semiconductor light-emitting device 700, the first semiconductor layer 712 having the uneven surface 720 may be formed by bonding the semiconductor light-emitting device 300A of FIG. 4A to the package substrate 510 by using the first bonding conductive layer 372 and the second bonding conductive layer 374, removing the substrate 302, and periodically forming an uneven pattern having a regular or irregular shape on an exposed surface of the first semiconductor layer 312.

Because the semiconductor light-emitting device 700 includes the first semiconductor layer 712 having the uneven surface 720, the amount of light emitted to the outside from among light generated by the active layer 314 is increased, thereby suppressing light loss and improving brightness.

FIG. 10A is a plan view illustrating major elements of a semiconductor light-emitting device according to an additional example embodiment of the inventive concepts. FIG. 10B is a cross-sectional view taken along line 10B-10B′ of FIG. 10A.

Referring to FIGS. 10A and 10B, a semiconductor light-emitting device 800 includes a conductive substrate 802, and a light-emitting structure 810 that is formed on the conductive substrate 802.

The conductive substrate 802 may be a metal substrate or a semiconductor substrate. In an example embodiment, the conductive substrate 802 may include at least one of Au, Ni, Al, Cu, W, Si, Se, and GaAs. For example, the conductive substrate 802 may be a Si substrate doped with Al.

A part of the conductive substrate 802 is covered by the light-emitting structure 810. A connection region C not covered by the light-emitting structure 810 is disposed on the conductive substrate 802. Although the connection region C is disposed adjacent to a corner portion of the conductive substrate 802 in FIGS. 10A and 10B, the present example embodiment is not limited thereto. For example, the connection region C may be formed on a central portion of the conductive substrate 802, or an arbitrary position between an edge portion and the central portion of the conductive substrate 802. Also, although the semiconductor light-emitting device 800 includes one connection region C in FIGS. 10A and 10B, the present example embodiment is not limited thereto. For example, the semiconductor light-emitting device 800 may include at least two connection regions C.

The light-emitting structure 810 includes a first semiconductor layer 812, an active layer 814, and a second semiconductor layer 816. A first electrode layer 830 is connected to the first semiconductor layer 812. A second electrode layer 840 is connected to the second semiconductor layer 816. A side wall of the light-emitting structure 810 and a part of the second electrode layer 840 are covered by an insulating film 822.

A portion of the first electrode layer 830 passes through the insulating film 822, the second electrode layer 840, the second semiconductor layer 816, and the active layer 814, and extends to a plurality of contact regions 812C of the first semiconductor layer 812. The first semiconductor layer 812 and the conductive substrate 802 may be electrically connected to each other through the first electrode layer 830. The first electrode layer 830 and the light-emitting structure 810 may be insulated from each other due to the insulating film 822 that is disposed between the first electrode layer 830 and the light-emitting structure 810.

An uneven pattern having a regular or irregular shape is formed on a surface of the first semiconductor layer 812 opposite to a surface of the first semiconductor layer 812 facing the active layer 814. Because the uneven pattern is formed on the surface 812B of the first semiconductor layer 812, the amount of light emitted to the outside from among light generated by the active layer 814 is increased, thereby suppressing light loss and improving brightness.

An electrode pad 850 for supplying external power to the second electrode layer 840 is formed on a portion of the second electrode layer 840 disposed on the connection region C. In an example embodiment, a connection unit (not shown) such as a wire may be connected to the electrode pad 850 to supply external power to the second electrode layer 840.

Materials of the first semiconductor layer 812, the active layer 814, the second semiconductor layer 816, the first electrode layer 830, and the insulating film 822 are substantially the same as those of the first semiconductor layer 112, the active layer 114, the second semiconductor layer 116, the first electrode layer 130, and the first insulating film 122 of FIG. 1A, and thus a detailed explanation thereof will not be given.

The second electrode layer 840 includes a first high-reflection metal layer 842 that contacts a portion of the second semiconductor layer 816, and a second high-reflection metal layer 844 that is spaced apart from the first high-reflection metal layer 842 and covers the first high-reflection metal layer 842. In an example embodiment, the first high-reflection metal layer 842 and the second high-reflection metal layer 844 may be spaced apart from each other on the second semiconductor layer 816, like the first high-reflection metal layer 142 and the second high-reflection metal layer 144 of the semiconductor light-emitting device 100 of FIG. 1A. Alternatively, the first high-reflection metal layer 842 and the second high-reflection metal layer 844 may contact each other at least partially on the second semiconductor layer 816, like the first high-reflection metal layer 242 and the second high-reflection metal layer 244 of the semiconductor light-emitting device 200 of FIG. 2A.

The second electrode layer 840 further includes a conductive electrode fixing layer 846 that is disposed between the first high-reflection metal layer 842 and the second high-reflection metal layer 844. In an example embodiment, the conductive electrode fixing layer 846 may have a portion contacting the second semiconductor layer 816, like the conductive electrode fixing layer 146 of the semiconductor light-emitting device 100 of FIG. 1A. Alternatively, at least a part of the conductive electrode fixing layer 846 may not contact the second semiconductor layer 816, like the conductive electrode fixing layer 246 of the semiconductor light-emitting device 200 of FIG. 2A.

The second electrode layer 840 further includes a conductive diffusion barrier film 848 that covers at least a part of the second high-reflection metal layer 844. In an example embodiment, the conductive diffusion barrier film 848 may be omitted.

The first high-reflection metal layer, the second high-reflection metal layer 844, the conductive electrode fixing layer 846, and the conductive diffusion barrier film 848 are substantially the same as the first high-reflection metal layer 142, the second high-reflection metal layer 144, the conductive electrode fixing layer 146, and the conductive diffusion barrier film 149 of FIGS. 1A through 1D, and thus a detailed explanation thereof will not be given.

A side wall of the light-emitting structure 810 is covered by a passivation layer 854. In an example embodiment, the passivation layer 854 may be formed of an oxide, a nitride, an insulating polymer, or a combination thereof. In an example embodiment, the passivation layer 854 may have a thickness of, but is not limited to, about 0.1 to 2 μm.

The passivation layer 854 may protect the light-emitting structure 810, particularly, the active layer 814, from the outside. Because the passivation layer 854 is formed on the side wall of the light-emitting structure 810, the possibility that the active layer 814 acts as a leakage current generating path during an operation of the semiconductor light-emitting device 800 may be eliminated. The passivation layer 854 may have a surface on which an uneven pattern having a regular or irregular shape is formed. Because the uneven pattern is formed on the surface of the passivation layer 854, light extraction efficiency of the semiconductor light-emitting device 800 may be improved.

A protective film 858 is formed on a surface of the second electrode layer 840 facing the connection region C. The protective film 858 may be formed on the second semiconductor layer 816 before the second electrode layer 840 is formed on the second semiconductor layer 816 during a process of manufacturing the semiconductor light-emitting device 800. The second electrode layer 840 may be formed on the second semiconductor layer 816 and the protective film 858. During a process of manufacturing the semiconductor light-emitting device 800, when semiconductor layers constituting the light-emitting structure 810 are to be etched to form the connection region C, the semiconductor layers may be etched by using the protective film 858 as an etch-stop layer. Accordingly, because a process of etching the semiconductor layers may stop before the second electrode layer 840 is exposed in the connection region C, and the second electrode layer 840 is not exposed to an etching atmosphere, the problem that a material of the second electrode layer 840 is attached to a surface of the active layer 814 which is exposed on a side wall of the light-emitting structure 810 through the connection region C may be solved.

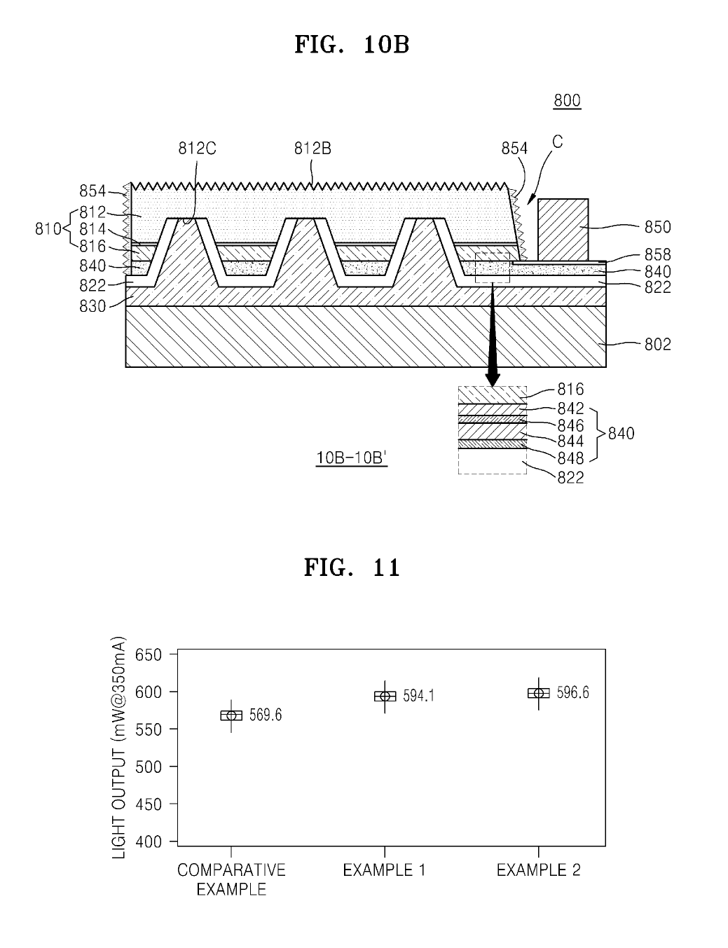

FIG. 11 is a graph illustrating a result obtained by comparing a light output of a semiconductor light-emitting device according to an example embodiment of the inventive concepts with a light output of a semiconductor light-emitting device according to a comparative example.

A semiconductor light-emitting device (Example 1) including a p electrode including a first high-reflection metal layer formed of Ag (1000 Å), a conductive electrode fixing layer having a stacked structure of a Ni layer (500 Å) and a Ti layer (100 Å), a second high-reflection metal layer formed of a Ag/Pd/Cu alloy a (1000 Å), and a conductive diffusion barrier film having a stacked structure of a Ti layer (1000 Å), a Ni layer (1000 Å), a Ti layer (1000 Å), and a Ni layer (1000 Å) was manufactured. Also, a semiconductor light-emitting device (Example 2) was manufactured under the same condition as that of Example 1 except that a second high-reflection metal layer of a p electrode is formed of a Ag/Pd/Cu alloy (2000 Å).

A semiconductor light-emitting device (Comparative Example) was manufactured under the same condition as that of Embodiment 1 except that a p electrode does not include a second high-reflection metal layer.

It is found from the graph of FIG. 11 that light outputs of the semiconductor light-emitting devices of Example 1 and Example 2 each including the p electrode including the second high-reflection metal layer are higher than a light output of the semiconductor light-emitting device of Comparative Example and thus brightnesses of the semiconductor light-emitting devices of Example 1 and Example 2 are higher than that of the semiconductor light-emitting device of Comparative Example.

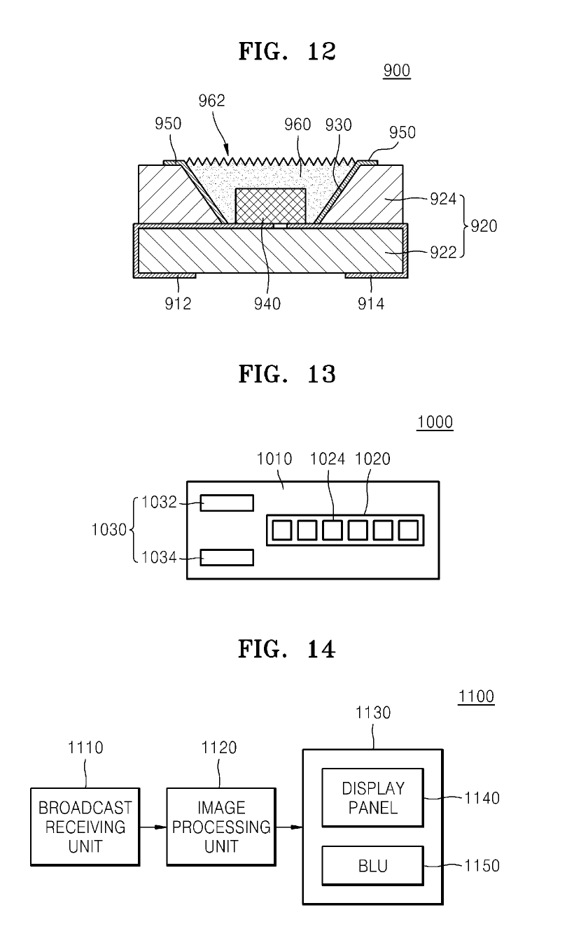

FIG. 12 is a cross-sectional view illustrating major elements of a light-emitting device package according to an example embodiment of the inventive concepts.

Referring to FIG. 12, a light-emitting device package 900 includes a cup-shaped package structure 920 on which electrode patterns 912 and 914 are formed. The package structure 920 includes a lower substrate 922 having a surface on which the electrode patterns 912 and 914 are formed, and an upper substrate 924 having a groove portion 930.

A semiconductor light-emitting device 940 is mounted on a bottom surface of the groove portion 930 by using flip-chip. The semiconductor light-emitting device 940 may include at least one of the semiconductor light-emitting devices 100, 200, 300A, 300B, 400, 500, 600, 700, and 800 of FIGS. 1A through 10B. The semiconductor light-emitting device 940 may be fixed to the electrode patterns 912 and 914 by using eutectic die bonding.

A reflective plate 950 is formed on an inner wall of the groove portion 930. The semiconductor light-emitting device 940 is covered by a transparent resin 960 that fills the groove portion 930 on the reflective plate 950. An uneven pattern 962 for improving light extraction efficiency is formed on a surface of the transparent resin 960. In an example embodiment, the uneven pattern 962 may be omitted.

The light-emitting device package 900 may be used as a blue light-emitting diode (LED) having high output/high efficiency, and may be used in a large display device, an LED TV, an RGB white lighting device, or a dimming lighting device.

FIG. 13 is a view illustrating a dimming system including a semiconductor light-emitting device, according to an example embodiment of the inventive concepts.

Referring to FIG. 13, a dimming system 1000 includes a light-emitting module 1020 and a power supply unit 1030 that are disposed on a structure 1010.

The light-emitting module 1020 includes a plurality of light-emitting device packages 1024. The plurality of light-emitting device packages 1024 may include at least one of the semiconductor light-emitting devices 100, 200, 300A, 300B, 400, 500, 600, 700, and 800 of FIGS. 1A through 10B.

The power supply unit 1030 includes an interface 1032 to which power is input, and a power supply control unit 1034 that controls power supplied to the light-emitting module 1020. The interface 1032 may include a fuse that cuts off over-current, and an electromagnetic shielding filter that shields an electromagnetic interference signal. The power supply control unit 1034 may include a rectification unit and a smoothing unit that convert alternating current which is input as power into direct current, and a constant voltage control unit that converts a voltage into a voltage suitable for the light-emitting module 1020. The power supply unit 1030 may include a feedback circuit device that compares the amount of light emitted by the plurality of light-emitting device packages 1024 with a preset amount of light, and a memory device that stores information such as desired brightness or color rendition.

The dimming system 1000 may be used as an indoor lighting device of a backlight unit, a lamp, or a flat lighting device used for a display device such as a liquid crystal display (LCD) device including an image panel, or as an outdoor lighting device of a signboard or a road sign. Alternatively, the dimming system 1000 may be used as a lighting device for a transportation unit such as a vehicle, a ship, or an airplane, an electric appliance such as a TV or a fridge, or a medical device.

FIG. 14 is a block diagram illustrating a display device including a semiconductor light-emitting device, according to an example embodiment of the inventive concepts.

Referring to FIG. 14, a display device 1100 includes a broadcast receiving unit 1110, an image processing unit 1120, and a display unit 1130.

The display unit 1130 includes a display panel 1140, and a backlight unit (BLU) 1150. The BLU 1150 includes light sources that generate light and driving elements that drive the light sources.

The broadcast receiving unit 1110 for selecting a channel of a broadcast signal received in a wired or wireless manner through a cable or the air sets an arbitrary channel from among a plurality of channels as an input channel and receives a broadcast signal through the input channel.

The image processing unit 1120 performs signal processing such as video decoding, video scaling, or frame rate conversion (FRC) on broadcast content output from the broadcast receiving unit 1110.

The display panel 1140 may include, but is not limited to, an LCD. The display panel 1140 displays the broadcast content on which signal processing has been performed by the image processing unit 1120. The BLU 1150 projects light to the display panel 1140 so that an image is displayed on the display panel 1140. The BLU 1150 may include at least one of the semiconductor light-emitting devices 100, 200, 300A, 300B, 400, 500, 600, 700, and 800 of FIGS. 1A through 10B.

A semiconductor light-emitting device according to the inventive concepts includes an electrode layer including a first high-reflection metal layer that contacts a first portion of a semiconductor region and reflects light from a light-emitting structure, and a second high-reflection metal layer that contacts the semiconductor region around the first high-reflection metal layer and reflects light from the light-emitting structure. Accordingly, light extraction efficiency is further improved by as much as a contact area between the second high-reflection metal layer and the semiconductor region, thereby maximizing light extraction efficiency. Also, because a metal which may form an ohmic contact with the semiconductor region is used as a material of the second high-reflection metal layer, an effective area of the electrode layer may be greater than that in a case with no second high-reflection metal layer. Accordingly, an operating voltage of the semiconductor light-emitting device is reduced, thereby improving efficiency of the semiconductor light-emitting device.

While the inventive concepts has been particularly shown and described with reference to example embodiments thereof, it will be understood that various changes in form and details may be made therein without departing from the spirit and scope of the following claims.

What is claimed is:

1. A semiconductor light-emitting device, comprising:
a semiconductor region including a light-emitting structure; and
an electrode layer including,
a first reflection metal layer contacting a first portion of the semiconductor region, the first reflection metal layer being configured to reflect light from the light-emitting structure, and
a second reflection metal layer contacting a second portion of the semiconductor region, and the second reflection metal layer being configured to reflect light from the light-emitting structure,
the second reflection metal layer being spaced apart from the first reflection metal layer and at least partially covering the first reflection metal layer.

2. The semiconductor light-emitting device of claim 1, wherein each of the first reflection metal layer and the second reflection metal layer has a reflectance of at least 80% with respect to light generated by the light-emitting structure.

3. The semiconductor light-emitting device of claim 1, wherein the first reflection metal layer and the second reflection metal layer are formed of the same material.

4. The semiconductor light-emitting device of claim 1, wherein the first reflection metal layer and the second reflection metal layer are formed of different materials.

5. The semiconductor light-emitting device of claim 1, wherein, in the semiconductor region, the second portion has a shape that surrounds the first portion.

6. The semiconductor light-emitting device of claim 1, wherein the first portion and the second portion are spaced apart from each other.

7. The semiconductor light-emitting device of claim 1, wherein the first portion and the second portion contact each other at least partially.

8. The semiconductor light-emitting device of claim 1, wherein,
the first reflection metal layer covers a first area of the semiconductor region,
the second reflection metal layer covers a second area of the semiconductor region, and
the second area is greater than the first area.

9. The semiconductor light-emitting device of claim 1, wherein each of the first reflection metal layer and the second reflection metal layer is formed of at least one selected from silver (Ag), aluminum (Al), nickel (Ni), chromium (Cr), palladium (Pd), copper (Cu), platinum (Pt), tin (Sn), tungsten (W), gold (Au), rhodium (Rh), iridium (Ir), ruthenium (Ru), magnesium (Mg), zinc (Zn), and an alloy thereof.

10. The semiconductor light-emitting device of claim 1, wherein,
the electrode layer further comprises a conductive electrode fixing layer between the first reflection metal layer and the second reflection metal layer, and
the electrode layer is formed of a material different from a material of each of the first reflection metal layer and the second reflection metal layer.

11. The semiconductor light-emitting device of claim 10, wherein the conductive electrode fixing layer comprises:
a close-contact layer on the first reflection metal layer,
a mechanical adhesive force between the first reflection metal layer and the first portion of the semiconductor region being greater when the close-contact layer is present as opposed to a mechanical adhesive force between the first reflection metal layer and the first portion of the semiconductor region when the close-contact layer is excluded from the conductive electrode fixing layer; and
an adhesive layer between the close-contact layer and the second reflection metal layer.

12. The semiconductor light-emitting device of claim 1, wherein the electrode layer further comprises a conductive diffusion barrier film covering the second reflection metal layer.

13. The semiconductor light-emitting device of claim 1, wherein the second reflection metal layer completely covers the first reflection metal layer.

14. A semiconductor light-emitting device comprising:
a semiconductor region including a light-emitting structure having a first semiconductor layer, an active layer, and a second semiconductor layer;
a first electrode layer contacting the first semiconductor layer; and
a second electrode layer contacting the second semiconductor layer,
at least one of the first electrode layer and the second electrode layer including a plurality of reflection metal layers,
the plurality of reflection metal layers being spaced apart from one another and overlapping with one another,
each of the plurality of reflection metal layers having a reflective surface contacting the semiconductor region.

15. The semiconductor light-emitting device of claim 14, wherein the plurality of reflection metal layers comprise:
a first reflection metal layer having a first reflective surface contacting a first portion of the semiconductor region; and
a second reflection metal layer having a second reflective surface contacting a second portion of the semiconductor region.

16. The semiconductor light-emitting device of claim 15, further comprising:
at least one conductive layer between the first reflection metal layer and the second reflection metal layer,
the at least one conductive layer having a third reflectance lower than a first reflectance of the first reflection metal layer and a second reflectance of the second reflection metal layer.

17. A semiconductor light-emitting device, comprising:
a semiconductor region including a light-emitting structure; and
a first electrode structure including a first metal layer and a second metal layer spaced apart from each other,
the first metal layer and the second metal layer contacting different areas of the semiconductor region,
the second metal layer extends over the first metal layer, and
the first metal layer and the second metal layer being configured to reflect light from the light-emitting structure.

18. The semiconductor light-emitting device of claim 17, wherein
the light-emitting structure includes a first semiconductor layer, a second semiconductor layer, and an active layer between the first and second semiconductor layers,
a second electrode structure contacts a first surface of the second semiconductor layer,
the second semiconductor layer has a second surface opposing the first surface, and
the second surface is uneven.

19. The semiconductor light-emitting device of claim 17, wherein
the first metal layer and the second metal layer contact a first area and a second area of the semiconductor region, respectively, and
the second metal layer covers an upper surface of the first metal layer.

20. The semiconductor light-emitting device of claim 19, wherein the first area and the second area of the semiconductor region abut each other.
